(19) United States
(12) Patent Application Publication
(10) Pub. No.: US 2016/0336527 A1
(43) Pub. Date: Nov. 17, 2016

(54) Method for Producing an Optoelectronic Arrangement, and Optoelectronic Arrangement

(71) Applicant: OSRAM OLED GMBH, Regensburg (DE)

(72) Inventors: Benjamin Claus Krummacher, Regensburg (DE); Simon Schicktanz, Regensburg (DE); Philipp Schwamb, Regensburg (DE)

(21) Appl. No.: 15/110,681

(22) PCT Filed: Jan. 27, 2015
(86) PCT No.: PCT/EP2015/051570

§ 371 Date: Jul. 8, 2016

(30) Foreign Application Priority Data
Feb. 6, 2014 (DE) 10 2014 101 489.8

(51) Int. Cl. H01L 51/52; H01L 51/44; H01L 51/00; H01L 51/56

(52) U.S. Cl. CPC H01L 51/52; H01L 51/56; H01L 51/44; H01L 51/0021

(57) ABSTRACT

A method for producing an optoelectronic arrangement and an optoelectronic arrangement. In an embodiment the method includes providing a connection carrier having a contact surface and two connection points, which are electrically conductively connected with the contact surface, providing an optoelectronic device having a connection surface, introducing an electrically conductive bonding material between the contact surface of the connection carrier and the connection surface of the optoelectronic device and heating the contact surface of the connection carrier by energizing the contact surface via the two connection points, wherein the electrically conductive bonding material is heated by the contact surface such that the bonding material melts or hardens.

This patent application is a national phase filing under section 371 of PCT/EP2015/051570, filed Jan. 27, 2015, which claims the priority of German patent application 10 2014 101 489.8, filed Feb. 6, 2014, each of which is incorporated herein by reference in its entirety.

### TECHNICAL FIELD

A method is provided for producing an optoelectronic arrangement. Furthermore, an optoelectronic arrangement is provided.

### BACKGROUND

U.S. Pat. No. 7,586,265 describes a method for producing an optoelectronic arrangement, and an optoelectronic arrangement.

### SUMMARY OF THE INVENTION

Embodiments of the present invention provide a method for producing an optoelectronic arrangement which is particularly cost-effective to implement.

According to at least one embodiment of the method, a connection carrier is provided. The connection carrier may for example comprise a base member configured to be electrically insulating and in which and on which conductor tracks and contact surfaces for connection and contacting of devices arranged on the connection carrier are provided. The connection carrier is, for example, a circuit board, a printed circuit board, a metal-core board or a flexible circuit board.

The connection carrier comprises a contact surface, which is electrically conductively connected with two connection points of the connection carrier. The contact surface, for example, takes the form of a top of the connection carrier. The contact surface may for example take the form of metallization on the top of a base member of the connection carrier.

The connection carrier may in this case also comprise two or more identical or similar contact surfaces, which are each connected electrically conductively with two connection points assigned to the contact surface. For example, assigned to each contact surface of the connection carrier are two or more, in particular precisely two, connection points, which are electrically conductively connected to just this contact surface and to no other contact surface of the connection carrier.

According to at least one embodiment of the method for producing an optoelectronic arrangement, an optoelectronic device is provided. The optoelectronic device may for example be a radiation-emitting or a radiation-detecting device. Furthermore, the device may have both radiation-emitting and radiation-detecting characteristics. The optoelectronic device may for example be a light-emitting diode, a photodiode, a solar cell, an organic light-emitting diode, an organic photodiode or an organic solar cell. The optoelectronic device comprises a connection surface, via which the optoelectronic device may be contacted electrically from outside for operation. It is possible in this respect that the optoelectronic device has two or more such connection surfaces.

According to at least one embodiment of the method, an electrically conductive bonding material is provided. The electrically conductive bonding material is a bonding material which is heat-hardenable, heat-activatable and/or heat-fusible. The electrically conductive bonding material may for example be a conductive adhesive or a solder material, for example a tin-lead solder.

According to at least one embodiment of the method, the electrically conductive bonding material is arranged between the contact surface of the connection carrier and the connection surface of the optoelectronic device.

According to at least one embodiment of the method, the contact surface of the connection carrier is heated by energizing the contact surface via the two connection points. In other words, the contact surface is energized via the two connection points such that an electric current flows through the contact surface. The ohmic heat generated thereby heats the contact surface. Since the electrically conductive bonding material is applied to the contact surface and is in direct contact with the contact surface for example at least in places, heating of the contact surface results in heating of the bonding material by means of the contact surface. The duration of energization and the current intensity with which the contact surface is energized via the connection points are selected such that the bonding material melts or hardens. If the bonding material is for example a heat-hardenable material, the bonding material hardens. If the bonding material is for example a heat-fusible bonding material, then the bonding material melts.

According to at least one embodiment of the method for producing an optoelectronic arrangement, the method comprises the following steps, which may be performed in particular in the stated sequence: providing a connection carrier having a contact surface and two connection points, which are electrically conductively connected with the contact surface, providing an optoelectronic device comprising a connection surface, introducing an electrically conductive bonding material between the contact surface of the connection carrier and the connection surface of the optoelectronic device, and heating the contact surface of the connection carrier by energizing the contact surface via the two connection points, wherein the electrically conductive bonding material is heated by the contact surface such that the bonding material melts or hardens.

Using the described method it is possible to heat up a bonding material in a purposeful and locally limited manner via the contact surface of a connection carrier for electromechanical connection of an optoelectronic device with the connection carrier. The otherwise necessary processing at high temperatures, as used for example with reflow soldering, generally results in the optoelectronic device being subjected to high thermal stress. In contrast thereto, by using local heating the bonding material may be heated purposefully according to the present method without the entire arrangement having to be heated to the same temperature. In this case, the connection carrier and the optoelectronic device are only heated locally at the point where contact surfaces of the connection carrier are arranged. In other words, no large-area heating of the optoelectronic device takes place, for example, but rather the temperature increase for melting or hardening the bonding material takes place purposefully and locally. This enables particularly careful electromechanical connection by way of the bonding material, wherein the process duration needed for heating of the contact surface and thus heating of the bonding material is not increased over conventional methods such as reflow soldering. With the described method in particular, an electromechanical connection may be produced by way of the bonding material in a process time of one minute or less.

The method may also be used for gentle bonding of particularly heat-sensitive devices to a connection carrier. The method is therefore suitable in particular for producing optoelectronic arrangements in which the optoelectronic device comprises at least one active layer, which is formed with an organic material. Such optoelectronic devices are for example organic light-emitting diodes or organic photodiodes.

With the method it is in particular also possible to apply a plurality of devices, i.e. two or more, for example four devices, in particular similar optoelectronic devices, to a common connection carrier without the thermal stress becoming too high for the devices or the connection carrier.

According to at least one embodiment of the method, the current intensity for energizing the contact surface is higher than the allowable operating current intensity for operation of the optoelectronic device. In other words, melting or hardening of the electrically conductive bonding material does not take place with the optoelectronic device in regular operation, but rather the contact surface is supplied with a current whose current intensity is significantly above the allowable current intensity for operation of the device. Due to the fact that the contact surface is electrically conductively connected with two connection points of the connection carrier via which the contact surface is energized, the connection points being short-circuited, on heating of the contact surface and thus on heating of the bonding material no energization of the device takes place, but rather current flow proceeds merely through the contact surface.

According to at least one embodiment of the method, the electrically conductive bonding material is arranged between the contact surface of the connection carrier and the connection surface of the optoelectronic device. For example, to this end the electrically conductive bonding material is applied to the contact surface of the connection carrier. If the electrically conductive bonding material is a fusible material, melting of the bonding material may then take place through heating of the contact surface by means of energization. Before or after melting, in a further method step the optoelectronic device is applied to the connection carrier in such a way that the electrically conductive bonding material is arranged between the contact surface of the connection carrier and the connection surface of the optoelectronic device.

If the electrically conductive bonding material is a heat-hardenable bonding material, the electrically conductive bonding material may be applied to the contact surface of the connection carrier and/or to the connection surface of the optoelectronic device. The contact surface of the connection carrier and the connection surface of the optoelectronic device are brought together such that the electrically conductive bonding material is arranged between them.

Subsequently, the contact surface is heated by energization and the bonding material is hardened by heating the bonding material. The bonding material is then heated to sufficiently high temperatures to harden it. For example, the bonding material is heated to temperatures of at least 170° C., preferably at least 180° C.

The bonding material may be applied to the contact surface of the connection carrier and/or the connection surface of the optoelectronic device by methods such as dispensing or printing. To bond connection carrier and optoelectronic device, a mechanical pressure may be exerted, in particular during heating of the contact surface, which presses the two components of the arrangement together. This pressure may also take place as early as prior to heating and after introduction of the electrically conductive bonding material between the contact surface of the connection carrier and the connection surface of the optoelectronic device.

According to at least one embodiment of the method, after heating the electrically conductive bonding material brings about an electrically conductive bond between the contact surface of the connection carrier and the connection surface of the optoelectronic device, such that the optoelectronic device may be electrically conductively contacted and operated via the connection points of the connection carrier. In other words, the optoelectronic device is soldered or conductively adhesively bonded to the connection carrier via the electrically conductive bonding material, wherein the electrically conductive bonding material enables an electrically conductive bond between the contact surface of the connection carrier and the associated connection point of the optoelectronic device. In the event that the connection carrier comprises two or more contact surfaces, which may be bonded to two or more connection surfaces of the optoelectronic device, the method described here may be performed for all the contact surfaces and connection surfaces of the arrangement. In this case, it is in particular possible to heat the different contact surfaces of the connection carrier at different times. For example, the contact surfaces of the connection carrier may be heated by energization in sequence one after the other. This further reduces the thermal stress on melting or hardening of the electrically conductive bonding material.

After heating of the electrically conductive bonding material, the connection carrier and the optoelectronic device are also connected mechanically together preferably via the electrically conductive bonding material, i.e. the electrically conductive bonding material brings about an electromechanical connection between the connection carrier and the optoelectronic device. In this case it is possible for the electrically conductive bonding material between the contact surfaces and the connection surfaces to constitute the sole electrical and mechanical connection between the components of the optoelectronic arrangement.

According to at least one embodiment of the method, during heating of the contact surface of the connection carrier electrical resistance is measured between the two connection points. In this way, the process may be monitored during heating. For instance, it is possible for sufficient hardening of the bonding material to be indicated by a fall in the resistance between the two connection points electrically conductively connected with the contact surface. Heating of the contact surface may then be terminated as soon as the resistance between the two connection points falls below a specified critical resistance. In this way, only as much heat as is absolutely essential is introduced into the optoelectronic device on mounting on the connection carrier.

According to at least one embodiment of the method, the area of a rectangular connection zone on the top of the connection carrier, which is defined by a curve which envelops the contact surface of the connection carrier, is larger than the contact surface. That is to say, if an imaginary curve in the form of a rectangle is placed on the top of the connection carrier around the contact surface, which curve completely encloses the contact surface, the area of this rectangular connection zone is larger than the area of the contact surface. This is in particular also the case if the rectangle is selected to be as small as possible and the imaginary curve completely envelops the contact surface. In other words, the contact surface is not embodied as an unpatterned rectangular surface, in which case the area of the rectangular connection zone would be equal to the area of the contact surface, but rather the contact surface is configured as a multiply connected and/or serpentine surface. The contact surface of the connection carrier is patterned in this embodiment and not configured as a simply connected surface. In this way, electrical resistance may be increased in comparison with a simply connected contact surface. This simplifies and accelerates heating of the contact surface by energization.

Furthermore, an optoelectronic arrangement is provided. The optoelectronic arrangement may be produced using a method described here. In other words, all the features disclosed for the method are also disclosed for the optoelectronic arrangement and vice versa.

According to at least one embodiment of the optoelectronic arrangement, the optoelectronic arrangement comprises a connection carrier, which has a contact surface and two connection points which are electrically conductively connected with the contact surface. In particular it is possible for the connection carrier to have two or more such contact surfaces with in each case two or more connection points. The optoelectronic arrangement further comprises an optoelectronic device which has a connection surface. The optoelectronic device may be supplied with power from outside via the connection surface. Preferably, the number of connection surfaces of the optoelectronic device corresponds to the number of contact surfaces of the connection carrier. The optoelectronic arrangement further comprises an electrically conductive bonding material, which may for example be a solder material or a conductive adhesive.

According to at least one embodiment of the optoelectronic arrangement, the area of a rectangular connection zone on the top of the connection carrier, which is defined by a curve which envelops the contact surface of the connection carrier, is larger than the contact surface. This is in particular also the case if the rectangular connection zone is selected to be as small as possible, wherein the imaginary curve completely envelops the contact surface. In other words, the contact surface is not rectangular but rather has a smaller area than the rectangular contact zone in which the contact surface is arranged. In this way, the contact surface has an increased electrical resistance.

According to at least one embodiment of the optoelectronic arrangement, the electrically conductive bonding material is arranged between the contact surface of the connection carrier and the connection surface of the optoelectronic device and the electrically conductive bonding material bonds the connection carrier and the optoelectronic device together. The bond which is brought about by the electrically conductive bonding material may in this case be an electrical and mechanical connection between the connection carrier and the optoelectronic device. Bonding using the electrically conductive bonding material here proceeds such that the optoelectronic device is electrically contactable and operable via the connection points of the connection carrier. In other words, an operating current for operating the optoelectronic device may be conducted via at least one connection point of the connection carrier, via the contact surface of the connection carrier and via the electrically conductive bonding material to the connection surface of the optoelectronic device.

According to at least one embodiment of the optoelectronic arrangement, an optoelectronic arrangement is provided which has a connection carrier comprising a contact surface and two connection points, which are electrically conductively connected with the contact surface, an optoelectronic device comprising a connection surface, and an electrically conductive bonding material, wherein the area of a rectangular connection zone on the top of the connection carrier, which is defined by a curve which envelops the contact surface of the connection carrier, is larger than the contact surface, the electrically conductive bonding material is arranged between the contact surface of the connection carrier and the connection surface of the optoelectronic device, and the electrically conductive bonding material bonds the connection carrier and the optoelectronic device together electrically conductively, such that the optoelectronic device is electrically contactable and operable via the connection points of the connection carrier.

In particular it is possible that, in an arrangement described here, a plurality of devices, i.e., two or more, for example four devices, in particular similar optoelectronic devices, are applied to the common connection carrier in the manner described.

The following embodiments relate equally to the method and the arrangement.

According to at least one embodiment, the contact surface of the connection carrier is configured so as in places to be serpentine and/or multiply connected. The contact surface is thus not an unpatterned rectangular surface but rather patterned for example in serpentine manner to increase the resistance of the contact surface. A contact surface which is not simply connected may for example be formed by a rectangular contact surface which comprises openings, i.e. which has regions in which material of the contact surface has been removed.

According to at least one embodiment, the connection carrier comprises a base member, on the top of which the contact surface of the connection carrier is arranged, wherein the connection points are arranged on the bottom of the connection carrier remote from the top. The connection points are for example connected with the contact surface via through-vias through the base member. In this way, the contact surface may be contacted via the connection points on the bottom remote from the top. It is thereby possible to arrange the optoelectronic component on the top of the connection carrier and to heat the contact surface from the bottom by energization.

According to at least one embodiment, in the contact zone the electrically conductive bonding material is in places in direct contact with the base member. Due to the fact that the contact surface of the connection carrier may be configured such that it is not simply connected or serpentine, it is possible for the bonding material to be in direct contact with the base member even in the contact zone. If the contact surface for example comprises openings, which serve to increase the electrical resistance of the contact surface, the bonding material may be in direct contact with the base member in these openings after heating. There, for example, the bonding material is surrounded at least in places in lateral directions, i.e. the directions which extend parallel to the main plane of extension of the connection carrier, by material of the contact surface.

### BRIEF DESCRIPTION OF THE DRAWINGS

The method described here and the arrangement described here are explained in greater detail below with reference to exemplary embodiments and the associated figures.

A first exemplary embodiment of a method described here is explained in greater detail with reference to the schematic sectional representations in FIGS. 1A to 1E.

A second exemplary embodiment of a method described here is explained in greater detail with reference to the schematic plan views in FIGS. 2A to 2C.

FIGS. 1E and 2C show exemplary embodiments of arrangements described here by way of schematic views.

Identical, similar or identically acting elements are provided with identical reference numerals in the figures. The figures and the size ratios of the elements illustrated in the figures relative to one another are not to be regarded as being to scale. Rather, individual elements may be illustrated on an exaggeratedly large scale for greater ease of depiction and/or better comprehension.

### DETAILED DESCRIPTION OF ILLUSTRATIVE EMBODIMENTS

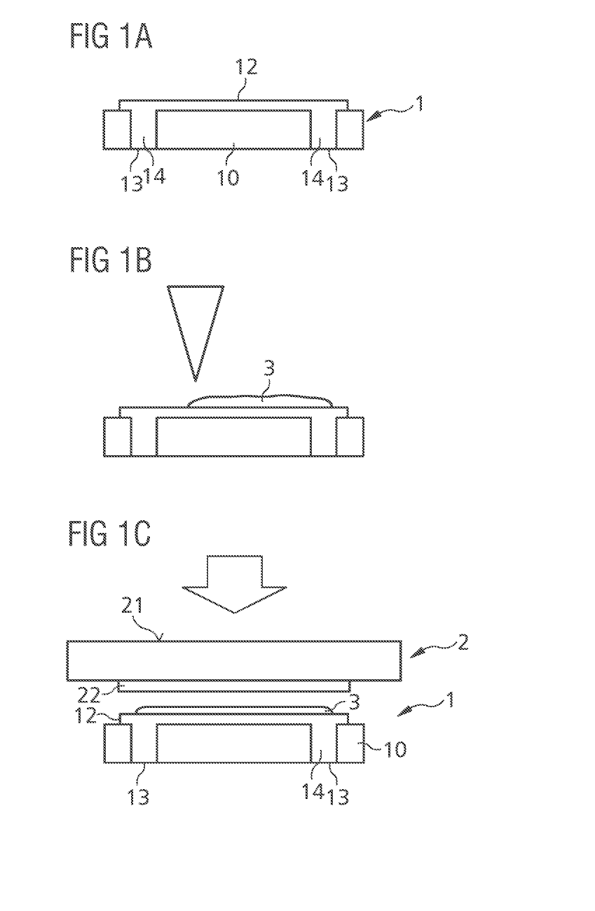

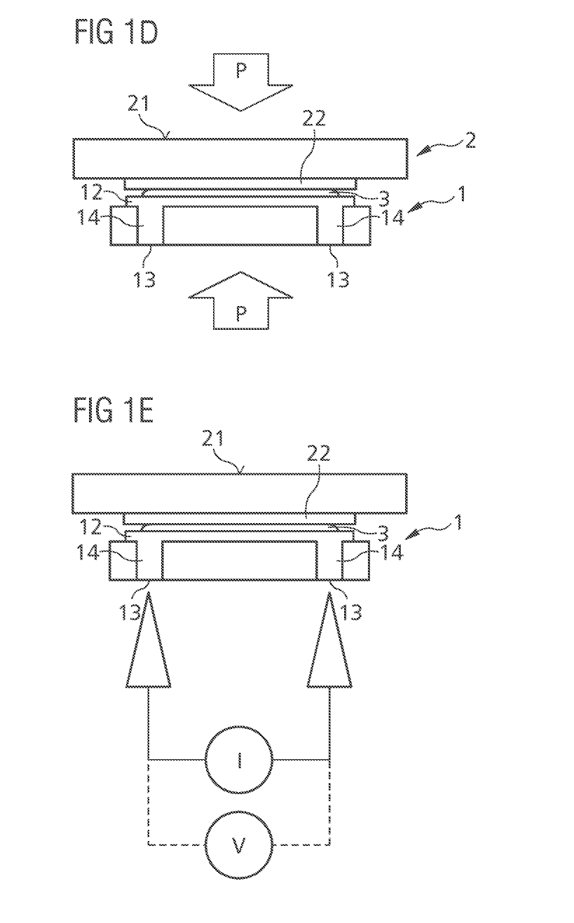

FIG. 1A shows a connection carrier 1 which is provided for the purposes of a method described here. The connection carrier 1 comprises a base member 10, which is formed with electrically insulating material. The base member 10 is formed for example with a ceramic material or a plastics material.

The contact surface 12, which may for example be formed by metallization of the base member, is formed on the top of the base member 10. Through-vias 14 extend in the base member 10 which connect the contact surface 12 with connection points 13 on the bottom of the base member 10 remote from the top.

In a next method step, FIG. 1B, an electrically conductive bonding material 3, for example a conductive adhesive or a solder material, is applied to the top of the base member on the contact surface 12. In a next method step, FIG. 1C, an optoelectronic device 2 is placed on the bonding material 3. The optoelectronic device 2 comprises a connection surface 22, which is brought into direct contact with the bonding material 3. The optoelectronic device is for example radiation-emitting or radiation-detecting, wherein the top of the optoelectronic device 2 remote from the connection carrier 3 comprises a radiation passage face 21.

In a next method step, FIG. 1D, pressure may be exerted on the bonding material 3 by the connection carrier 1 and by the optoelectronic device 2, which may lead to better distribution of the bonding material 3.

In the next method step, FIG. 1E, a heating current is introduced at the connection points 13, which heats the contact surface 12 due to the electrical resistance of the latter. The heating melts or hardens the bonding agent 3. For process monitoring, the voltage V present between the connection points 13 may be measured. If for example the value falls below a critical resistance, this may indicate that hardening of the bonding material 3 is complete and the procedure can be terminated.

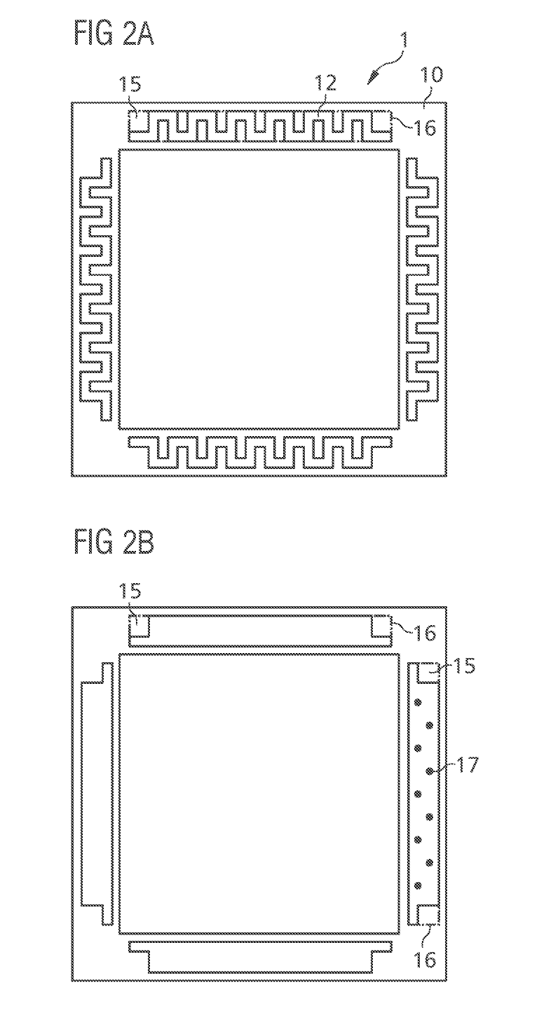

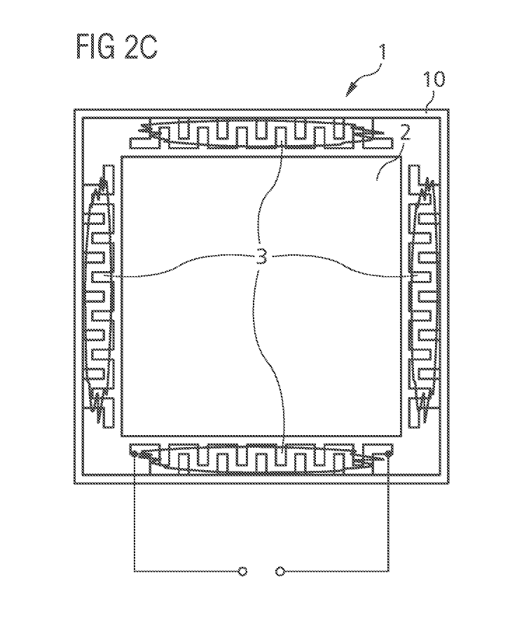

A further exemplary embodiment of a method described here is explained in greater detail in conjunction with FIGS. 2A to 2C. FIGS. 2A and 2B are schematic plan views of different possible ways of configuring the contact surfaces 12 of the connection carrier 1. In the exemplary embodiment of FIG. 2A the contact surface 12 is of serpentine configuration. The contact surface 12 is surrounded by an envelope curve 16 which has a rectangular connection zone 15. The rectangular connection zone 15 has a larger area than the contact surface 12. In other words, not all of the area enclosed by the envelope curve 16 is filled with the electrically conductive material of the contact surface, but rather only part of this area. In this way, the resistance of the contact surface is higher compared to a contact surface in which the entire rectangular zone enclosed by the curve 16 is electrically conductive. The higher resistance results in simplified heating of the contact surface using a method described here.

Alternatively, the contact surface may comprise openings 17, as shown for example in FIG. 2B, which result in the contact surface not being simply connected. These openings 17 also increase the electrical resistance of the contact surface in contrast with a completely filled contact surface.

FIG. 2C shows how the bonding material 3 is arranged between the connection carrier 1 and the optoelectronic device 2 on the contact surface 12. It is apparent therefrom that the bonding material 3 may in places be in direct contact with the base member 10 in the contact zone 15.

The method described here is particularly well suited to mounting optoelectronic components with organic layers which are particularly heat-sensitive on connection carriers. The method is inexpensive, since the optoelectronic component may be electrically and mechanically connected directly to the connection carrier without any further connection element merely via the electrically conductive bonding material. The thermal stress on the optoelectronic component is particularly low, since only the contact surfaces are locally heated. No overall heating of the optoelectronic component takes place, as would for example have been the case in conventional methods such as reflow soldering.

Measurement of the voltage drop between the connection points 13 of the connection carrier provides the possibility of instantaneous process monitoring, which allows conclusions to be drawn as to the quality of the electromechanical connection brought about by the electrically conductive bonding agent 3. The method described here is moreover readily implementable on an industrial scale using simple automation technology. Since heating takes place by forming a short-circuit over the contact surface 12, the method may also be performed using simple technical means.

The description made with reference to exemplary embodiments does not restrict the invention to these embodiments. Rather, the invention encompasses any novel feature and any combination of features, including in particular any combination of features in the claims, even if this feature or this combination is not itself explicitly indicated in the claims or exemplary embodiments.

1-13. (canceled)

14. A method for producing an optoelectronic arrangement, the method comprising:
providing a connection carrier having a contact surface and two connection points, which are electrically conductively connected with the contact surface;
providing an optoelectronic device comprising a connection surface;
introducing an electrically conductive bonding material between the contact surface of the connection carrier and the connection surface of the optoelectronic device; and
heating the contact surface of the connection carrier by energizing the contact surface via the two connection points, wherein the electrically conductive bonding material is heated by the contact surface such that the bonding material melts or hardens.

15. The method according to claim 14, wherein, while heating the contact surface of the connection carrier, an electrical resistance is measured between the two connection points, and wherein heating the contact surface comprises terminating the heating as soon as the resistance between the two connection points falls below a specified critical resistance.

16. The method according to claim 14, wherein a current intensity for energizing the contact surface is higher than an allowable operating current intensity for operation the optoelectronic device.

17. The method according to claim 14, wherein introducing the electrically conductive bonding material comprises arranging the electrically conductive bonding material on the contact surface of the connection carrier.

18. The method according to claim 14, wherein, after heating the electrically conductive bonding material, forming an electrically conductive bond between the contact surface of the connection carrier and the connection surface of the optoelectronic device such that the optoelectronic device is electrically contactable and operable via the connection points of the connection carrier.

19. The method according to claim 14, wherein, while heating the contact surface of the connection carrier, measuring an electrical resistance between the two connection points.

20. The method according to claim 19, further heating the contact surface comprises terminating the heating as soon as the resistance between the two connection points falls below a specified critical resistance.

21. The method according to claim 14, wherein an area of a rectangular connection zone on top of the connection carrier, which is defined by a curve which envelops the contact surface of the connection carrier, is larger than the contact surface.

22. The method according to claim 14, wherein the connection carrier comprises a base member, on a top of which the contact surface of the connection carrier is arranged and wherein the connection points are arranged on a bottom of the connection carrier remote from the top.

23. The method according to claim 22, wherein the electrically conductive bonding material is in direct contact with the base member in a contact zone.

24. The method according to claim 14, wherein the optoelectronic device comprises at least one active layer, the active layer comprising an organic material.

25. An optoelectronic arrangement comprising:
a connection carrier comprising a contact surface and two connection points, which are electrically conductively connected with the contact surface;
an optoelectronic device comprising a connection surface; and
an electrically conductive bonding material,
wherein an area of a rectangular connection zone on a top of the connection carrier, which is defined by a curve which envelops the contact surface of the connection carrier, is larger than the contact surface,
wherein the electrically conductive bonding material is arranged between the contact surface of the connection carrier and the connection surface of the optoelectronic device, and
wherein the electrically conductive bonding material bonds electrically conductively the connection carrier and the optoelectronic device together such that the optoelectronic device is electrically contactable and operable via the connection points of the connection carrier.

26. The arrangement according to claim 25, wherein the contact surface of the connection carrier is serpentine and/or multiply connected.

27. The arrangement according to claim 25, wherein the contact surface of the connection carrier is configured so as in places to be serpentine and/or multiply connected.

28. The arrangement according to claim 25, wherein the connection carrier comprises a base member, on the top of which the contact surface of the connection carrier is arranged, and wherein the connection points are arranged on a bottom of the connection carrier remote from the top.

29. The arrangement according to claim 28, wherein the electrically conductive bonding material is in direct contact with the base member in a contact zone.

30. The arrangement according to claim 25, wherein the optoelectronic device comprises at least one active layer, the active layer comprising an organic material.

31. An optoelectronic arrangement comprising:
a connection carrier comprising a contact surface and two connection points, which are electrically conductively connected with the contact surface;
an optoelectronic device comprising a connection surface; and
an electrically conductive bonding material,
wherein an area of a rectangular connection zone on a top of the connection carrier, which is defined by a curve which envelops the contact surface of the connection carrier, is larger than the contact surface,
wherein the electrically conductive bonding material is arranged between the contact surface of the connection carrier and the connection surface of the optoelectronic device,
wherein the electrically conductive bonding material bonds electrically conductively the connection carrier and the optoelectronic device together such that the optoelectronic device is electrically contactable and operable via the connection points of the connection carrier, and
wherein the contact surface of the connection carrier is serpentine and/or multiply connected.
